(19) United States
(12) Patent Application Publication
(10) Pub. No.: US 2011/0081531 A1
(43) Pub. Date: Apr. 7, 2011

(54) BASE MATERIAL FOR GROWING SINGLE CRYSTAL DIAMOND AND METHOD FOR PRODUCING SINGLE CRYSTAL DIAMOND SUBSTRATE

(75) Inventor: Hitoshi NOGUCHI, Annaka (JP)

(73) Assignee: SHIN-ETSU CHEMICAL CO., LTD., Tokyo (JP)

(21) Appl. No.: 12/876,531

(22) Filed: Sep. 7, 2010

(30) Foreign Application Priority Data
Oct. 2, 2009 (JP) 2009-230776

(51) Int. Cl. C30B 23/02; B32B 15/04; B32B 7/02

(52) U.S. Cl. 428/213; 117/95; 428/446; 428/332

(57) ABSTRACT

The present invention is a base material for growing a single crystal diamond comprising a single crystal silicon substrate, a MgO film heteroepitaxially grown on a side of the single crystal silicon substrate where the single crystal diamond is to be grown, and an iridium film or a rhodium film heteroepitaxially grown on the MgO film. As a result, there is provided a base material for growing a single crystal diamond and a method for producing a single crystal diamond substrate which can grow the single crystal diamond having a large area and good crystallinity and produce a high quality single crystal diamond substrate at low cost.

### BACKGROUND OF THE INVENTION

1. Field of the Invention

The present invention relates to a base material for growing a single crystal diamond and a method for producing a single crystal diamond substrate.

2. Description of the Related Art

Diamond has a wide band gap of 5.47 eV and a very high dielectric breakdown electric field intensity of 10 MV/cm, and it has the highest thermal conductivity in materials. Therefore, if this is used for an electronic device, the device is advantageous as a high output power device.

Furthermore, the diamond has a high drift mobility and is the most advantageous as a high speed power device among semiconductors in comparison of Johnson performance index.

The diamond is thus said to be the ultimate semiconductor suitable for high frequency/high power electronic devices, and accordingly studies of various kinds of electronic devices using a single crystal diamond as a substrate have progressed.

Now, a single crystal diamond for producing a diamond semiconductor is, in many cases, the diamond referred to as an Ib type formed by a high-pressure-high-temperature method (HPHT) or an IIa type of which purity is enhanced.

However, it is difficult to grow in size, while the HPHT single crystal diamond having high crystallinity can be obtained. In addition, a price of the diamond becomes extremely high when its size becomes big and consequently, it is difficult to put it into practical use as the substrate for the devices.

In view of this, a CVD single crystal diamond formed by a vapor deposition method has been also studied to provide a low cost single crystal diamond substrate having a large area.

Recently, there was reported a homoepitaxial CVD single crystal diamond that is homoepitaxially grown directly on the HPHT single crystal diamond base material (a seed base material) by the vapor deposition method (the 20th diamond symposium lecture summary (2006), pp. 6-7).

In this method, since the base material and the single crystal diamond grown are composed of the same material, it is difficult to separate these, and there are cost problems that the base material needs implanting ions in advance, a lengthy wet etching separation treatment after the growth and the like. There is also another problem that crystallinity of the single crystal diamond to be obtained deteriorates to a certain degree due to the ion implantation of the base material.

As an alternative, there was reported a CVD single crystal diamond heteroepitaxially grown by a CVD method on a single crystal iridium (Ir) film heteroepitaxially grown on a single crystal MgO base material (a seed base material) (Jpn. J. Appl. Phys. Vol. 35 (1996), pp. L1072-L1074).

However, in this method, there is a problem that the base material and the single crystal diamond grown are finely broken due to stress generated between the single crystal MgO substrate and the single crystal diamond grown via the single crystal Ir film (sum of internal stress and heat stress). Moreover, the crystallinity of the single crystal diamond to be obtained does not achieve a satisfactory level since crystallinity of an available single crystal MgO that is the seed base material is not sufficient.

### SUMMARY OF THE INVENTION

The present invention was accomplished in view of the aforementioned problems, and it is an object of the present invention to provide a base material for growing a single crystal diamond and a method for producing a single crystal diamond substrate which can grow the single crystal diamond having a large area and good crystallinity and produce a high quality single crystal diamond substrate at low cost.

In order to accomplish the above object, the present invention provides a base material for growing a single crystal diamond comprising at least a single crystal silicon substrate, a MgO film heteroepitaxially grown on a side of the single crystal silicon substrate where the single crystal diamond is to be grown, and an iridium film or a rhodium film heteroepitaxially grown on the MgO film.

In case of the single crystal silicon substrate as described above, the substrate having good crystallinity can be obtained at low cost, and thereby the iridium film or the rhodium film can be grown with good crystallinity as well as the MgO film to be formed on its surface having good crystallinity. Thus, the single crystal diamond having high crystallinity can be obtained by growing the single crystal diamond on the base material. Moreover, in case of the single crystal silicon substrate, since a thermal expansion coefficient of silicon is relatively near to that of diamond, the stress generated due to thermal expansion is small during the growth of the single crystal diamond, and also the single crystal diamond and the base material are scarcely broken. When the base material has the MgO film on the single crystal silicon substrate and the iridium film or the rhodium film, they function as a good buffer layer during the growth of the single crystal diamond.

As described above, the base material for growing a single crystal diamond according to the present invention can grow the single crystal diamond having a large area and high crystallinity at low cost.

In this case, a thickness of the single crystal silicon substrate is preferably 0.03 mm to 20.00 mm.

The single crystal silicon substrate having the above-described thickness enables handling to make easy, and when the thickness is 20.00 mm or less, a double-side polishing and the like can be performed well.

In this case, the MgO film can be heteroepitaxially grown on the single crystal silicon substrate by a sputtering method or an electron beam evaporation method.

In this manner, the MgO film of the base material according to the present invention can be grown by the sputtering method or the electron beam evaporation method.

In this case, a thickness of the MgO film is preferably 5 Å to 100 μm.

In this manner, when the thickness of the MgO film is 5 Å or more, film thickness uniformity and the crystallinity become higher. When the thickness is 100 μm or less, the stress generated between the base material and the single crystal diamond is small, thereby the single crystal diamond can be surely grown and moreover the base material becomes low-cost.

In this case, the iridium film or the rhodium film can be heteroepitaxially grown on the MgO film by a sputtering method.

In this manner, the iridium film or the rhodium film of the base material according to the present invention can be heteroepitaxially grown by the sputtering method.

In this case, a thickness of the iridium film or the rhodium film is preferably 5 Å to 100 μm.

In this manner, when the thickness of the iridium film or the rhodium film is 5 Å or more, film thickness uniformity and the crystallinity are sufficiently high. When the thickness is 100 μm or less, the stress generated between the base material and the single crystal diamond is small, thereby the single crystal diamond can be surely grown and moreover the base material becomes low-cost.

In this case, a surface of the iridium film or the rhodium film is preferably subjected to a bias treatment.

In this manner, the base material subjected to the bias treatment forms a diamond nucleus on its surface and can thereby grow the single crystal diamond with good crystallinity at a sufficient growth rate.

Furthermore, the present invention provides a method for producing a single crystal diamond substrate comprising at least the steps of: preparing a single crystal silicon substrate; heteroepitaxially growing a MgO film on the prepared single crystal silicon substrate; heteroepitaxially growing an iridium film or a rhodium film on the MgO film heteroepitaxially grown; heteroepitaxially growing a single crystal diamond on the iridium film or the rhodium film heteroepitaxially grown; separating the single crystal diamond heteroepitaxially grown to obtain the single crystal diamond substrate.

In case of the single crystal silicon substrate as described above, the substrate having good crystallinity can be prepared at low cost, the MgO film and the iridium film or the rhodium film can be grown on the single crystal silicon substrate with good crystallinity, and the single crystal diamond having high crystallinity can be grown on the iridium film or the rhodium film having good crystallinity. Moreover, in case of the single crystal silicon substrate, since the stress due to thermal expansion generated during the growth of the single crystal diamond is small, both of the single crystal silicon substrate and the single crystal diamond are scarcely broken. Moreover, since the single crystal diamond is grown on the iridium film or the rhodium film, the material of which is different from that of the single crystal diamond, the single crystal diamond can be easily separated in the step of separating.

As described above, the method for producing according to the present invention can efficiently produce the single crystal diamond substrate having good crystallinity at low cost.

In this case, before the step of heteroepitaxially growing the single crystal diamond, a bias treatment is preferably preliminarily performed on a surface where the single crystal diamond is to be heteroepitaxially grown.

In this manner, when the bias treatment is preliminarily performed, a diamond nucleus is formed on the surface and the single crystal diamond can be grown with good crystallinity at a sufficient growth rate.

In this case, the single crystal diamond can be heteroepitaxially grown by a microwave CVD method or a direct-current plasma CVD method in the step of heteroepitaxially growing the single crystal diamond.

In this manner, the single crystal diamond can be heteroepitaxially grown by the microwave CVD method or the direct-current plasma CVD method in the method for producing according to the present invention.

As described above, the base material for growing a single crystal diamond and the method for producing a single crystal diamond substrate according to the present invention can grow the single crystal diamond having a large area and high crystallinity at low cost and produce a high quality single crystal diamond substrate at good productivity.

### BRIEF DESCRIPTION OF THE DRAWINGS

FIG. 1 is a schematic view showing an example of embodiments of the base material for growing a single crystal diamond according to the present invention; and

FIG. 2 are flow charts showing an example of embodiments of the method for producing a single crystal diamond substrate according to the present invention.

### DETAILED DESCRIPTION OF THE PREFERRED EMBODIMENTS

Conventionally, in an attempt to obtain the single crystal diamond by a cost-advantageous CVD method, there are problems that a portion of the single crystal diamond grown cannot be easily separated without damage and it is difficult to grow the single crystal diamond having high crystallinity and a large area. Accordingly, the present inventor repeatedly keenly conducted studies on a type and structure of the base material and a method for producing a single crystal.

As a result, the present inventor found that when the single crystal silicon substrate, in which the difference in a linear expansion coefficient from the diamond is relatively small, is used as the seed base material, which mainly generates the stress at an interfaces between a single crystal diamond layer and the base material, the stress generated due to thermal expansion is smaller in comparison with the case of using a conventional MgO seed base material and that a break of all of them can be consequently prevented (the linear expansion coefficient diamond: 1.1×10⁻⁶/K, Si: 4.2×10⁻⁶/K, MgO: 13.8×10⁻⁶/K).

In addition, the single crystal silicon substrate having higher crystallinity in comparison with the conventional MgO seed base material can be relatively easily obtained, and when the single crystal silicon substrate is used as the seed base material, the single crystal. MgO film on the seed base material and the single crystal Ir (iridium) film or the single crystal Rh (rhodium) film on the MgO film can be heteroepitaxially grown with good crystallinity. The present inventor also found that when these high crystallinity materials are used for the base material and the single crystal diamond is heteroepitaxially grown thereon by the CVD method, the single crystal diamond having high crystallinity can be obtained. The present inventor further confirmed that the single crystal diamond grown on this base material can be easily separated by a wet etching method and can be also separated by removing a part of the base material by a mechanical polishing method, and brought the present invention to completion.

Hereinafter, an example of embodiments of the present invention will be explained in detail with reference to the drawings. However the present invention is not restricted thereto.

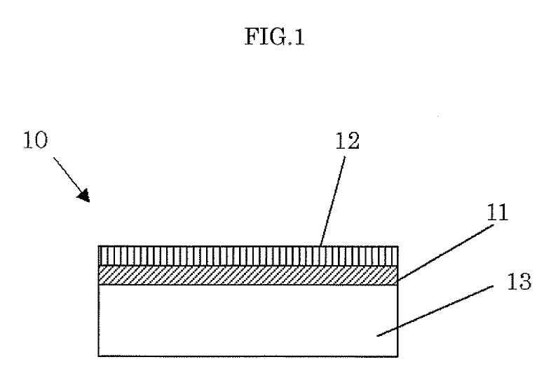

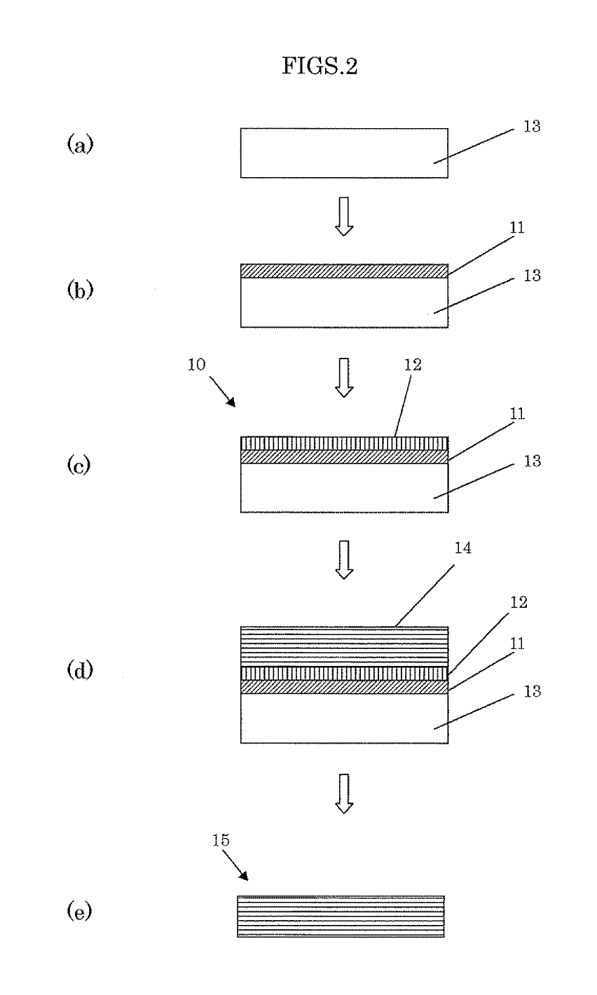

FIG. 1 is a schematic view showing an example of embodiments of the base material for growing a single crystal diamond according to the present invention. FIG. 2 are flow charts showing an example of embodiments of the method for producing a single crystal diamond substrate according to the present invention.

The base material for growing a single crystal diamond 10 according to the present invention as shown in FIG. 1 comprises the single crystal silicon substrate 13, the MgO film 11 heteroepitaxially grown on the side of the single crystal silicon substrate 13 where the single crystal diamond is to be grown, and the iridium film or the rhodium film 12 heteroepitaxially grown on the MgO film 11.

In the event that the seed base material is the single crystal silicon substrate as described above, since it is produced in large quantities for a semiconductor device and the single crystal silicon substrate having very good crystallinity can be obtained at low cost, the iridium film or the rhodium film consequently has good crystallinity as well as the MgO film to be formed on the substrate surface having good crystallinity. The single crystal diamond having high crystallinity can be obtained by growing the single crystal diamond on the base material. Moreover, in case of the single crystal silicon substrate, since the thermal expansion coefficient of silicon is relatively near to that of diamond, the single crystal diamond and the base material itself are scarcely broken by the stress due to thermal expansion. When the base material has the iridium film or the rhodium film in addition to the MgO film on the single crystal silicon substrate, they function as good buffer layers during the growth of the single crystal diamond. That is, as mentioned above, the linear expansion coefficient of the MgO is greatly different from that of the diamond. On the other hand, the MgO is a form of a film in the present invention and can thereby absorb the stress, and it does not particularly become issue with regard to the growth of the diamond. Instead, there is an advantage that existence of the MgO film enables the single crystal diamond film to be easily delaminated when it is separated after the growth of the diamond.

Hereinafter, an example of a method of fabricating the base material for growing a single crystal diamond as described above and the method for producing a single crystal diamond substrate according to the present invention will be explained with reference to FIG. 2.

First, as shown in FIG. 2(a), the single crystal silicon substrate 13 is prepared in the present invention.

The single crystal silicon substrate 13 to be prepared is not restricted in particular. For example, the substrate having a diameter of 25 mm that is subjected to a double-side polishing can be prepared. As described above, when the single crystal silicon substrate is used as the seed base material, the single crystal silicon substrate having higher crystallinity in comparison with the conventional MgO seed base material can be relatively easily obtained, and thereby the MgO film thereon and the single crystal iridium film or the single crystal rhodium film can be grown with good crystallinity.

The thickness of the single crystal silicon substrate 13 is preferably 0.03 mm to 20.00 mm.

When the thickness of this single crystal silicon substrate is 0.03 mm or more, handling is easy. When the thickness is 20.00 mm or less, it is not unnecessarily thick and is cost-advantageous, a final double-side polishing and the like can be easily performed, and thereby a condition of its surface can be made better. The heteroepitaxial growth can be consequently performed well in a subsequent step.

Next, as shown in FIG. 2(b), the MgO film 11 is heteroepitaxially grown on the single crystal silicon substrate 13, for example, by the sputtering method or the electron beam evaporation method.

Growth conditions and the like are not restricted in particular, but the thickness of the MgO film 11 is preferably 5 Å to 100 μm.

As described above, when the thickness of the MgO film is 5 Å or more, the film thickness uniformity and the crystallinity can be made high. When the thickness is 100 μm or less, the stress generated between the base material and the single crystal diamond is small, thereby the single crystal diamond can be more surely grown, and moreover the base material becomes cost-advantageous and low-cost.

Next, as shown in FIG. 2(c), the iridium film or the rhodium film 12 is heteroepitaxially grown on the MgO film 11, for example, by the sputtering method.

In this case, the growth conditions and the like are also not restricted in particular. For example, it can be grown at a sufficient growth rate by the R. F. magnetron sputtering method, and the thickness of the iridium film or the rhodium film 12 is preferably 5 Å to 100 μm.

As described above, when the thickness of the iridium film or the rhodium film is 5 Å or more, the film thickness uniformity and the crystallinity are high. When the thickness is 100 μm or less, the stress generated between the base material and the single crystal diamond is small, thereby the single crystal diamond can be more surely grown and moreover the cost can be reduced.

The base material for growing a single crystal diamond 10 according to the present invention can be fabricated by the foregoing way. Here, before the growth of the single crystal diamond in a subsequent step, the bias treatment is preferably performed on the surface of the iridium film or the rhodium film 12 of the base material 10.

This bias treatment first performs a pretreatment for forming the diamond nucleus by a direct-current discharge in which an electrode of the base material side is set at a cathode in advance so that the diamond nucleus having a uniform orientation on the surface of the iridium film or the rhodium film is formed, for example, by the method as described in Japanese Patent Laid-open (Kokai) No. 2007-238377. Accordingly, the single crystal diamond can be grown with good crystallinity at a sufficient growth rate in a subsequent step.

Next, as shown in FIG. 2(d), the single crystal diamond 14 is heteroepitaxially grown, for example, by the microwave CVD method or the direct-current plasma CVD method.

As described above, in the case of growing the single crystal diamond on the base material of the present invention, since the single crystal silicon substrate is used as the seed base material, which is the thickest among the base material and is apt to generate the stress due to thermal expansion, the stress is hard to generate during the growth of the single crystal diamond and the break can be prevented. In addition, since the MgO film and the iridium film or the rhodium film have good crystallinity, the single crystal diamond having high crystallinity can be grown.

Next, as shown in FIG. 2(e), the single crystal diamond substrate 15 is obtained by separating the single crystal diamond 14.

The method of separating it is not restricted in particular. For example, after dividing it into the single crystal diamond/the iridium film and the MgO film/the single crystal silicon substrate by immersing it into the wet etching solution such as phosphoric acid solution, hot mixed acid or the like, the single crystal diamond substrate can be obtained by removing the remaining iridium film by the mechanical polishing method. Alternatively, the iridium film/the MgO film/the single crystal silicon substrate may be removed by the mechanical polishing method at once without immersing it into the wet etching solution.

Using the base material for growing a single crystal diamond and the method for producing a single crystal diamond substrate according to the present invention as described above enables the single crystal diamond substrate having a large area and high crystallinity, which is usable for device application, to be produced at low cost.

### EXAMPLES

Hereinafter, the present invention will be more specifically explained by showing Example and Comparative Examples. However, the present invention is not restricted thereto.

### Example

As the seed base material, there was prepared a double-side-polished single crystal silicon substrate having a diameter of 25.0 mm, a thickness of 0.38 mm and an orientation (100). The MgO film having a thickness of 0.2 μm was epitaxially grown on the side of the seed base material where the single crystal diamond was to be grown by the electron beam evaporation method in a vacuum under the conditions of a substrate temperature of 900° C.

Next, the iridium (Ir) film was heteroepitaxially grown on the single crystal MgO film. The film-forming was completed by performing the sputtering by the R. F. magnetron sputtering method in which an target was Ir under the conditions of an Ar gas of 6×10⁻² Torr and a substrate temperature of 700° C., until a thickness of the single crystal Ir film became 1.5 μm.

For the sake of electrical continuity in the bias treatment and the direct-current plasma CVD, the Ir film having a thickness of 1.5 μm was also grown on a back surface under the same conditions except for making the base material temperature 100° C.

Next, the bias treatment was performed for forming the diamond nucleus on the surface of the single crystal Ir film of the base material.

First, the base material was placed on a negative voltage-applying electrode (cathode) of a bias treatment apparatus, and then vacuum exhaust was performed. Next, after the base material was heated to 600° C., a hydrogen-diluted methane gas of 3 vol. % was introduced so that pressure became 160 hPa (120 Torr). Then, the bias treatment was performed. That is, DC voltage was applied to both the electrodes to apply a prescribed DC electricity.

Finally, the single crystal diamond was heteroepitaxially grown on the base material subjected to the bias treatment at 900° C. for 30 hours by the direct-current plasma CVD method.

After finishing the growth, a product taken out from a bell jar was a laminated structure of the diamond/Ir/MgO/Si without the break. Then, a base material part of the Ir/MgO/Si on the back surface was removed to get self-standing structure of the single crystal diamond (the single crystal diamond substrate). This surface was also subjected to a final polishing so that it was finished so as to have surface roughness of a usable level for device application.

It was confirmed that the obtained single crystal diamond substrate had sufficient crystallinity as a result of evaluation by raman spectroscopy, XRD rocking curve, X-sectional TEM and cathodoluminescence (CL).

### Comparative Example 1

Except for using a double-side-polished single crystal MgO substrate having a 5.0 mm square, a thickness of 0.5 mm and an orientation (100) as the seed base material, there was prepared the base material by the Ir growth and the bias treatment, and the single crystal diamond was heteroepitaxially grown thereon by the direct-current plasma CVD method as with Example.

Then, the bell jar was opened to observe the product in the chamber. As a result, both of the base material and a portion of the grown single crystal diamond were broken into fine pieces having an approximate 1.0 mm square. One of the pieces was taken out and its crystallinity was evaluated. As a result, it was observed that raman full width at half maximum was wide, a lot of dislocation defects existed in X-sectional TEM and the like and thus the crystallinity was an insufficient level for device application.

### Comparative Example 2

Except for using a double-side-polished single crystal MgO substrate having a 5.0 mm square, a thickness of 120 μm and an orientation (100) as the seed base material, there was prepared the base material by the Ir growth and the bias treatment, and the single crystal diamond was heteroepitaxially grown thereon by the direct-current plasma CVD method as with Example.

Then, the bell jar was opened to observe the product in the chamber. As a result, both of the base material and a portion of the grown single crystal diamond were broken into fine pieces having an approximate 1.0 mm square.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A base material for growing a single crystal diamond comprising at least a single crystal silicon substrate, a MgO film heteroepitaxially grown on a side of the single crystal silicon substrate where the single crystal diamond is to be grown, and an iridium film or a rhodium film heteroepitaxially grown on the MgO film.

2. The base material for growing a single crystal diamond according to claim 1, wherein a thickness of the single crystal silicon substrate is 0.03 mm to 20.00 mm.

3. The base material for growing a single crystal diamond according to claim 1, wherein the MgO film is heteroepitaxially grown on the single crystal silicon substrate by a sputtering method or an electron beam evaporation method.

4. The base material for growing a single crystal diamond according to claim 1, wherein a thickness of the MgO film is 5 Å to 100 μm.

5. The base material for growing a single crystal diamond according to claim 2, wherein a thickness of the MgO film is 5 Å to 100 μm.

6. The base material for growing a single crystal diamond according to claim 3, wherein a thickness of the MgO film is 5 Å to 100 μm.

7. The base material for growing a single crystal diamond according to claim 1, wherein the iridium film or the rhodium film is heteroepitaxially grown on the MgO film by a sputtering method.

8. The base material for growing a single crystal diamond according to claim 1, wherein a thickness of the iridium film or the rhodium film is 5 Å to 100 μm.

9. The base material for growing a single crystal diamond according to claim 2, wherein a thickness of the iridium film or the rhodium film is 5 Å to 100 μm.

10. The base material for growing a single crystal diamond according to claim 3, wherein a thickness of the iridium film or the rhodium film is 5 Å to 100 μm.

11. The base material for growing a single crystal diamond according to claim 4, wherein a thickness of the iridium film or the rhodium film is 5 Å to 100 μm.

12. The base material for growing a single crystal diamond according to claim 5, wherein a thickness of the iridium film or the rhodium film is 5 Å to 100 μm.

13. The base material for growing a single crystal diamond according to claim 6, wherein a thickness of the iridium film or the rhodium film is 5 Å to 100 μm.

14. The base material for growing a single crystal diamond according to claim 7, wherein a thickness of the iridium film or the rhodium film is 5 Å to 100 μm.

15. The base material for growing a single crystal diamond according to claim 1, wherein a surface of the iridium film or the rhodium film is subjected to a bias treatment.

16. A method for producing a single crystal diamond substrate comprising at least the steps of:
preparing a single crystal silicon substrate;
heteroepitaxially growing a MgO film on the prepared single crystal silicon substrate;
heteroepitaxially growing an iridium film or a rhodium film on the MgO film heteroepitaxially grown;
heteroepitaxially growing a single crystal diamond on the iridium film or the rhodium film heteroepitaxially grown; and
separating the single crystal diamond heteroepitaxially grown to obtain the single crystal diamond substrate.

17. The method for producing a single crystal diamond substrate according to claim 16, wherein before the step of heteroepitaxially growing the single crystal diamond, a bias treatment is preliminarily performed on a surface where the single crystal diamond is to be heteroepitaxially grown.

18. The method for producing a single crystal diamond substrate according to claim 16, wherein the single crystal diamond is heteroepitaxially grown by a microwave CVD method or a direct-current plasma CVD method in the step of heteroepitaxially growing the single crystal diamond.

19. The method for producing a single crystal diamond substrate according to claim 17, wherein the single crystal diamond is heteroepitaxially grown by a microwave CVD method or a direct-current plasma CVD method in the step of heteroepitaxially growing the single crystal diamond.
